(19) United States
(12) Patent Application Publication
(10) Pub. No.: US 2022/0416211 A1
(43) Pub. Date: Dec. 29, 2022

(54) LIGHT-EMITTING DEVICE, DISPLAY APPARATUS, AND LIGHTING APPARATUS HAVING THE SAME

(71) Applicant: Najing Technology Corporation Limited, Hangzhou, Zhejiang (CN)

(72) Inventors: Changgua ZHEN, Hangzhou, Zhejiang (CN); Xinyan GU, Hangzhou, Zhejiang (CN)

(21) Appl. No.: 17/777,649

(22) PCT Filed: Nov. 20, 2020
(86) PCT No.: PCT/CN2020/130632

§ 371 Date: May 18, 2022

(30) Foreign Application Priority Data
Nov. 22, 2019 (CN) 201911158538.4

(51) Int. Cl. H01L 51/52; H01L 51/50; H01L 27/32

(52) U.S. Cl. CPC H01L 51/5268; H01L 51/5092; H01L 51/502; H01L 27/3218

(57) ABSTRACT

Provided in the present disclosure are a light-emitting device, a display apparatus having the same, and a lighting apparatus. The light-emitting device includes a light-emitting unit disposed in a sub-region. The light-emitting unit includes a light-emitting functional layer, a light extraction functional layer and a part of a light transmissive substrate, which are disposed in a stacked manner. The light extraction functional layer is located on a light-exiting side of the light-emitting functional layer. A straight line segment that passes through geometric center of a light-exiting surface of each light-emitting unit and whose two ends are respectively connected with edge line of the light-exiting surface is defined as a first straight line segment, and the shortest length of the first straight line segment is defined as W. In a direction perpendicular to the light transmissive substrate, a thickness of the light-emitting unit without reflective electrode is T.

### TECHNICAL FIELD

The present disclosure relates to the field of optical technology, and in particular, relates to a light-emitting device, a display apparatus and a lighting apparatus having the same.

### BACKGROUND

Light extraction technology has a wide range of applications in display and lighting devices, in display device, the function of it is to collect light from LED beads which are regarded as “point light sources” and spread the light to the entire plane, and light is concentrated by some light extraction structures, such as an array of prisms, and then emitted toward the direction of a filter. Completely different from conversion of point light source to planar light source, lighting panel such as OLED is a planar light source with soft light, and there is no need for improving luminance uniformity. The application of light extraction structure in the structure of OLED device is mainly to guide out the light that cannot be emitted due to total reflection, thus improving the overall light extraction efficiency of the device and prolonging the lifetime of the device.

Other than the application of such “planar light sources”, it is difficult to find a micro-light-emitting device (such as a device having pixel structure) which is a point light source using a light extraction structure in the market. The reason is that the application of light extraction structures not only has insignificant light extraction effect for small-area light-emitting devices, but also has very limited improvement in light extraction ratio. They may also cause light mixing due to unreasonable configuration, such as the white light generated from mixing lights of AGB sub-pixels, resulting in the failure to accurately display a picture. Therefore, it is generally believed that light extraction technology is not suitable for micro-light-emitting devices.

### SUMMARY

The primary object of this disclosure is to provide a light-emitting device, a display apparatus and a lighting apparatus thereof to solve the problem of the prior art in small-area light-emitting devices.

In order to achieve the above object, according to one aspect of the present disclosure, a light-emitting device is provided, including: a light transmissive substrate; an isolation structure, disposed on a first surface of the light transmissive substrate, forming at least one sub-region by the isolation structure; a light-emitting functional layer, disposed in the sub-region by one-to-one correspondence, including a light transmissive electrode, a light emitting layer and a reflective electrode, wherein the light transmissive electrode and the reflective electrode are independently located on opposite sides of the light emitting layer; a light extraction functional layer, disposed in one-to-one correspondence with the light-emitting functional layer; wherein, the light-emitting functional layer, the light extraction functional layer and a part of the light transmissive substrate, which are stacked by one-to-one correspondence, constitute each light-emitting unit; structure of each light-emitting unit is selected from structure A, structure B and structure C, the structure A includes the light-emitting functional layer, the light extraction functional layer and the part of the light transmissive substrate which are successively stacked, the structure B includes the light-emitting functional layer, the part of the light transmissive substrate and the light extraction functional layer which are successively stacked, and the structure C includes light extraction functional layer, the light-emitting functional layer and the part of the light transmissive substrate which are successively stacked; light-exiting direction of the structure A and the structure B is from the reflective electrode to the light transmissive substrate, and light-exiting direction of the structure C is from the reflective electrode to the light extraction functional layer; a straight line segment that passes through geometric center of a light-exiting surface of each light-emitting unit and whose two ends are respectively connected with edge line of the light-exiting surface is defined as a first straight line segment, and the shortest length of the first straight line segment is defined as W; in a direction perpendicular to the light transmissive substrate, a thickness difference of the light-emitting unit and the reflective electrode is defined as T in the structure A and the structure B, and a and a thickness difference of sum of thickness of the light extraction functional layer and the light-emitting functional layer and the thickness of the reflective electrode is defined as T in the structure C; in the structure A, the structure B and the structure C, the T is less than the W.

Optionally, T/W [symbol] 1/10.

Optionally, T/W [symbol] 1/20.

Optionally, T/W [symbol] 1/30.

Optionally, 300 nm [symbol] T [symbol] 1 mm, W [symbol] 3 μm.

Optionally, the light-exiting surface has a pattern of polygon formed by a plurality of straight line segments or a pattern surrounded by at least one arc segment.

Optionally, the light-emitting functional layer further includes a hole injection transport layer and an electron injection transport layer, the hole injection transport layer and the electron injection transport layer are located on opposite sides of the light emitting layer, and the light transmissive electrode is located on a side of the hole injection transport layer or the electron injection transport layer away from the light emitting layer.

Optionally, the light emitting layer is a quantum dot light emitting layer or an organic luminescent material layer.

Optionally, the structure of each light emitting unit is the structure A or the structure C, and the light extraction functional layer includes a light extraction layer and an interface layer which is located between the light transmissive electrode and the light extraction layer.

Optionally, the light-emitting device includes a plurality of the light-emitting units for emitting different colors of light, and the different colors of light is independently selected from at least one of red light, green light, blue light and white light.

Optionally, the light-emitting device is one of an OLED device, a LED device and a QLED device.

Optionally, the structure of each light emitting unit is the structure B, and the light extraction functional layer includes a light extraction layer and an interface layer which is located on a side of the light extraction layer away from the light transmissive substrate.

According to another aspect of the present disclosure, a display apparatus is provided, including a light-emitting device which is the aforesaid light-emitting device, wherein the isolation structure is a pixel isolation structure, and the sub-region is a sub-pixel region.

According to another aspect of the present disclosure, a lighting apparatus is provided, including a light-emitting device which is the aforesaid light-emitting device, wherein the isolation structure is a frame, and the light-emitting unit is disposed within the frame.

Applying the technical scheme of the present disclosure, the light-emitting device including a light-emitting unit disposed in a sub-region is provided. The light-emitting unit includes a light-emitting functional layer, a light extraction functional layer and a part of a light transmissive substrate, which are disposed in a stacked manner. The light extraction functional layer is located on a light-exiting side of the light-emitting functional layer. A straight line segment that passes through geometric center of a light-exiting surface of each light-emitting unit and whose two ends are respectively connected with edge line of the light-exiting surface is defined as a first straight line segment, and the shortest length of the first straight line segment is defined as W. In a direction perpendicular to the light transmissive substrate, a thickness of the light-emitting unit without reflective electrode is T. By making the T less than the W, the light extraction functional layer can meet the universally applicable application conditions, so that the light extraction effect can be significant whether the light-emitting unit is applied to small-area light-emitting devices or large-area light-emitting devices, thus improving the light extraction efficiency of the light-emitting unit and prolonging the lifetime of the device.

### BRIEF DESCRIPTION OF THE DRAWINGS

The drawings constituting a part of the present disclosure are used to provide a further understanding of the present disclosure, and the schematic embodiment of the present disclosure and the description thereof are for explaining the present disclosure, and does not constitute an improper limitations of the present disclosure. In the drawings:

FIG. 1 shows a partial cross-sectional schematic of a top-emitting light-emitting device according to an embodiment of the present disclosure.

FIG. 2 shows a partial cross-sectional schematic of a bottom-emitting light-emitting device according to an embodiment of the present disclosure.

FIG. 3 shows a partial cross-sectional schematic of a bottom-emitting light-emitting device according to another embodiment of the present disclosure.

FIG. 4 shows overlook structure diagrams of the position of the first straight line segment in each light-exiting surface of different light-emitting devices provided in accordance with the present disclosure embodiments, in which the dashed line is the shortest length of the first straight line segment.

The above drawings include the following reference signs:

10, light transmissive substrate; 20, light-emitting functional layer; 210, light transmissive electrode; 220, light emitting layer; 230, reflective electrode; 30, light extraction functional layer.

### DETAILED DESCRIPTION

It should be noted that the embodiments of the present disclosure and the features of the embodiments may be combined with each other in case of no conflict. The disclosure will be described in detail below with reference to the figures and in conjunction with the embodiments.

As used herein, the singular forms “a,” “an” and “the” are intended to include the plural forms as well, unless the context clearly indicates otherwise. It should be understood that when an element (such as a layer, a film, a region, or a substrate) is described as being “on” another element, the element can be directly on the other element, or intervening elements may also be present.

In order to enable a person skilled in the art to have a better understanding of the solution of the present disclosure, the technical solutions in the embodiments of the present disclosure will be clearly and completely described below with reference to the figures, but obviously, the described embodiments are merely a part of the embodiments of the disclosure rather than all of the embodiments. All other embodiments obtained by a person of ordinary skill in the art based on the embodiments of the present disclosure without creative efforts should fall within the scope of the present disclosure.

It should be noted that the terms “first”, “second”, and the like in the specification and claims of the present disclosure are used to distinguish similar objects, and are not necessarily used to describe a particular order or sequence. It should be understood that the number so used may be interchangeable when appropriate to facilitate the description of embodiments of the disclosure disclosed herein. Furthermore, the terms “include” and “have”, as well as any variants thereof, are intended to cover a non-exclusive inclusion, for example, processes, methods, systems, products, or devices that include a series of steps or units are not necessarily limited to include those steps or units explicitly listed, and may include other steps or units not explicitly listed or inherent to such processes, methods, products or devices.

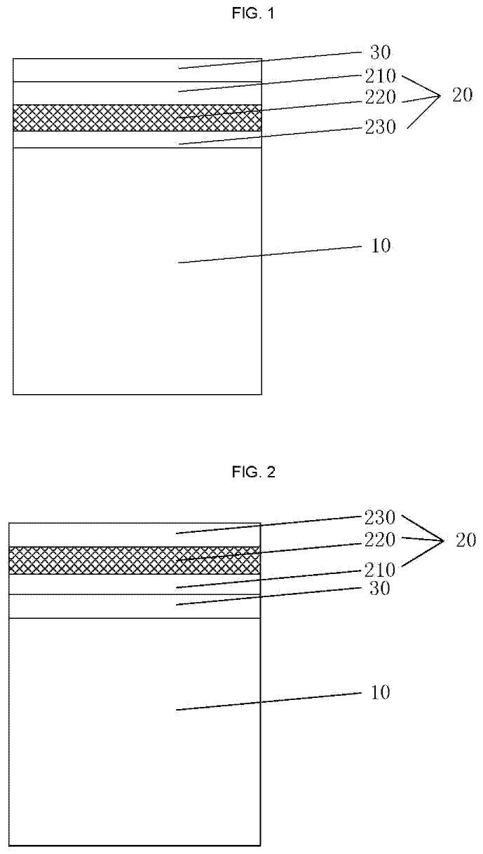

According to the background of the present disclosure, light extraction structures in the prior art are not suitable for small-area light-emitting devices. The inventors of the present disclosure have conducted researches on the above problem, and the present disclosure has provided a light-emitting device, as shown in but not limited to FIGS. 1 to 3, including a light transmissive substrate 10, an isolation structure, a light-emitting functional layer 20 and a light extraction functional layer 30, the isolation structure is disposed on a first surface of the light transmissive substrate 10, and at least one sub-region is formed by the isolation structure; the light-emitting functional layer 20 is disposed in the sub-region by one-to-one correspondence, and the light-emitting functional layer 20 includes a light transmissive electrode 210, a light emitting layer 220 and a reflective electrode 230, wherein the light transmissive electrode 210 and the reflective electrode 230 are independently located on opposite sides of the light emitting layer 220; the light extraction functional layer 30 is disposed in one-to-one correspondence with the light-emitting functional layer 20.

The light-emitting functional layer 20, the light extraction functional layer 30 and a part of the light transmissive substrate 10, which are stacked by one-to-one correspondence, constitute each light-emitting unit; structure of each light-emitting unit is selected from structure A, structure B and structure C, the structure A includes the light-emitting functional layer 20, the light extraction functional layer 30 and the part of the light transmissive substrate 10 which are successively stacked, the structure B includes the light-emitting functional layer 20, the part of the light transmissive substrate 10 and the light extraction functional layer 30 which are successively stacked, and the structure C includes the light extraction functional layer 30, the light-emitting functional layer 20 and the part of the light transmissive substrate 10 which are successively stacked; light-exiting direction of the structure A and the structure B is from the reflective electrode 230 to the light transmissive substrate 10, and light-exiting direction of the structure C is from the reflective electrode 230 to the light extraction functional layer 30. “the part of the light transmissive substrate” refers to the partial light transmissive substrate corresponding to the contact surface of its adjacent layer.

A straight line segment that passes through geometric center of a light-exiting surface of each light-emitting unit and whose two ends are respectively connected with edge line of the light-exiting surface is defined as a first straight line segment, and the shortest length of the first straight line segment is defined as W, as shown in FIG. 4, (a) is a rhombus, (b) is a polygon, (c) is a rectangle, (d) is an elliptical; in a direction perpendicular to the light transmissive substrate 10, a thickness difference of the light-emitting unit and the reflective electrode 230 is defined as T in the structure A and the structure B, and a thickness difference of sum of thickness of the light extraction functional layer and the light-emitting functional layer and the thickness of the reflective electrode 230 is defined as T in the structure C; in the structure A, the structure B and the structure C, the T is less than the W.

Since the light-emitting functional layer in each light-emitting unit is disposed respectively in the sub-region by one-to-one correspondence, the shape of the cross section of the sub-region determines the shape of the light-exiting surface of the light-emitting unit. By making the T less than the W, the light extraction functional layer can meet the universally applicable application conditions, so that the light extraction effect can be significant whether the light-emitting unit is applied to small-area light-emitting devices or large-area light-emitting devices, thus improving the light extraction efficiency of the light-emitting unit and prolonging the lifetime of the device.

In some embodiments, the isolation structure is a weblike stereoscopic pattern, so that the meshes of the weblike pattern enclose a plurality of sub-regions. In some embodiments, a material of the isolation structure is an opaque insulating material. In some embodiments, a height of the isolation structure is greater than the total height of the light-emitting functional layer 20 and the light extraction functional layer 30. In some embodiments, the light transmissive substrate is a polymer or glass substrate having a thin film transistor array structure.

In some embodiments, the size of the light-exiting surface of each light-emitting unit, such as W, can be measured by means of a microscope.

Each sub-region or each light-exiting surface may be the same shape or different shapes, which may be the same size or different sizes. In some embodiments, each light-emitting unit can be independently designed to achieve high light extraction efficiency.

The light-emitting device of the present disclosure may include a plurality of light-emitting units, each of which emits different wavelengths of light by the light-emitting function layer 20, wherein, the aforesaid different wavelengths of light not only can refer to different light having single wavelength, but also can be understood as light with different wavelength ranges; the different wavelengths of light can be different colors of light, such as red light, green light, blue light, and white light, but is not limited thereto. Those skilled in the art can make reasonable selection of the number of light-emitting units and the light-emitting wavelength of each of the light-emitting units according to the actual need, so that the light-emitting unit can be applied to an OLED device, a LED device, or a QLED device, and the LED device includes a mini-LED device and micro LED device.

The light extraction functional layer 30 is disposed in one-to-one correspondence with the light-emitting functional layer 20 in each light-emitting unit, so that each light extraction functional layer corresponding to different wavelengths of incident light has different improvement ratios of light extraction efficiency when the different wavelengths of incident light emitted from the light extraction functional layer 30 passes through each light extraction functional layer. Therefore, the external quantum efficiencies of different light-emitting units that emits different wavelengths of light in the light-emitting device can be optimized, thereby not only improving the luminous efficiency of the device, but also enabling the final external quantum efficiency of different light-emitting units to be close, thereby realizing even degradation and prolonging the lifetime of the device.

The improvement ratio of light extraction efficiency refers to the improvement ratio of the external quantum efficiency of the light-emitting unit. In some embodiments, a light-emitting unit with the highest initial (without the light extraction layer) external quantum efficiency is defined as a first light-emitting unit, a light-emitting unit with the lowest initial external quantum efficiency is defined as a third light-emitting unit, and a light-emitting unit with the initial external quantum efficiency between the highest initial external quantum efficiency and the lowest initial external quantum efficiency is defined as a second light-emitting unit, an improvement ratio of the external quantum efficiency of the first light-emitting unit by the light extraction functional layer 30 is X₁, an improvement ratio of the external quantum efficiency of the second light-emitting unit by the light extraction functional layer 30 is X₂, and an improvement ratio of the external quantum efficiency of the third light-emitting unit by the light extraction functional layer 30 is X₃, wherein the X₁, the X₂ and the X₃ are not equal, and X_{N}=(Q₂−Q₁)/Q₁ is defined, wherein, the N is any natural number from 1 to 3, the Q₁ is the initial external quantum efficiency of the corresponding light-emitting unit, and the Q₂ is the actual external quantum efficiency of the corresponding light-emitting unit.

Those skilled in the art can provide the light extraction functional layers 30 with different ratios of extraction efficiency for the light-emitting units with different colors of light. In some embodiments, the first light-emitting unit may be a light-emitting unit that emits red light in the light-emitting device, and the second light-emitting unit may be a light-emitting unit that emits green light in the light-emitting device, and the third light-emitting unit may be a light-emitting unit that emits blue light in the light-emitting device. In general, the initial external quantum efficiencies of the first light-emitting unit, the second light-emitting unit and the third light-emitting unit decrease sequentially, since the initial external quantum efficiency of the three light-emitting units corresponding to RGB (red, green, blue) is sequentially lowered, the improvement ratio needs to be successively increased: X₃>X₂>X₁. It should be noted that under some exceptional circumstances, the initial external quantum efficiency of each of the light-emitting units may close to each other, or the latter being higher than the former. The light-emitting device having the light-emitting units may be an RGB light-emitting device, or the RGBW (red, green, blue, white) light-emitting device.

In some embodiments, X₂=X₁=0, X₃>0; or, X₁=0, X₂>0, X₃>0; or, X₃>X₂>X₁; or, X₃ [symbol] 3.

In some embodiments, in the light-emitting device of the present disclosure, the actual external quantum efficiency deviations among each of the light-emitting units are within ±15%. Specifically, the actual external quantum efficiency deviation of each light-emitting unit=(the actual external quantum efficiency of each light-emitting unit−the average value of the actual external quantum efficiency of all light-emitting units)±the average value of the actual external quantum efficiency of all light-emitting units.

In some embodiments, in the light-emitting device of the present disclosure, the actual external quantum efficiency deviations among each of the light-emitting units are within ±30%.

In some embodiments, the actual external quantum efficiency deviations among each of the light-emitting units are within ±10%.

In some embodiments, the actual external quantum efficiency deviations among each of the light-emitting units are within 5%.

In some embodiments, in order to adjust improvement ratio of the external quantum efficiency of the light-emitting unit by using the light extraction functional layer 30, the light extraction functional layer 30 can be a light scattering layer having scattering particles, the scattering particles include, but are not limited to, one or a combination of zinc oxide, aluminum oxide, zirconium oxide and titanium oxide, etc., and forming the raw material of the light extraction functional layer 30 may also include one or a combination of additives, polymers and curable adhesive, etc.

In order to make the light extraction functional layers 30 corresponding to the different wavelengths of incident light have different improvement ratio of light extraction efficiency, the efficiencies of the light-emitting units having different emission wavelengths can be coordinated, in some embodiments, thicknesses of the light extraction functional layers 30 corresponding to different wavelengths of incident light are different, the thickness of the light extraction functional layer corresponding to the first light-emitting unit is defined as H₁, the thickness of the light extraction functional layer corresponding to the second light-emitting unit is defined H₂, and the thickness of the light extraction functional layer corresponding to the third light-emitting unit is defined as H₃, wherein the H₁, the H₂, and the H₃ are not equal.

In other embodiments, in order to adjust external quantum efficiency improvement ratio, volume percentages of the light extraction functional layers with scattering particles are adjusted, the volume percentage of the scattering particles of the light extraction functional layer corresponding to the first light-emitting unit is defined as V₁, the volume percentage of the scattering particles of the light extraction functional layer corresponding to the second light-emitting unit is defined as V₂, and the volume percentage of the scattering particles of the light extraction functional layer corresponding to the third light-emitting unit is defined as V₃, wherein the V₁, the V₂ and the V₃ are not equal.

In other embodiments, in order to adjust external quantum efficiency improvement ratio, refractive indexes of the scattering particles in the light extraction functional layers are adjusted, the refractive index of the scattering particles of the light extraction functional layer corresponding to the first light-emitting unit is defined as K₁, the refractive index of the scattering particles of the light extraction functional layer corresponding to the second light-emitting unit is defined as K₂, and the refractive index of the scattering particles of the light extraction functional layer corresponding to the third light-emitting unit is defined as K₃, wherein the K₁, the K₂ and the K₃ are not equal.

In addition to the embodiments of the light scattering layer having scattering particles as the light extraction functional layer 30, the light extraction functional layer 30 may also be a homogeneous material layer. When the light extraction functional layer 30 is a homogeneous material layer, the material forming the light extraction functional layer 30 may be selected from one of a polymer resin, metal oxide particles, and semiconductor materials.

The light extraction functional layer 30 may also be a layer of refractive index gradation material, the material forming the light extraction functional layer 30 may be selected from more of a polymer resin, metal oxide particles and semiconductor materials, such as a scattering system formed by stacking a plurality of semiconductor materials, or a metal compound layer with continuous change of n value obtained by changing the sputtering atmosphere step by step to change slightly the composition of metal compound, and its effective refractive index=(the volume percentage of the first component×the refractive index of the first component) (the volume percentage of the second component×the refractive index of the second component)+ . . . (the volume percentage of the nth component×the refractive index of the nth component), and the n is greater than 1.

In order to improve the light extraction effect of the light extraction functional layer 30 applied to the light-emitting device, in some embodiments, T/W [symbol] 1/10; in some embodiments, T/W [symbol] 1/20; in some embodiments, T/W [symbol] 1/30.

In order to make the light extraction functional layer 30 have a significant light extraction effect in both a small-area light-emitting device and a large-area light-emitting device, in some embodiments, 300 [symbol] T [symbol] 1 nm, W [symbol] 3 m.

In the light-emitting device of the present disclosure, each sub-region has a first cross section that is parallel to the light transmissive substrate 10, which is the same as the shape of the light-exiting, surface of the light-emitting unit, and can be a combination of a straight line segment and/or an arc segment, such as a pattern composed of a straight line segment and an arc segment, a polygon formed by a plurality of straight line segments or a pattern surrounded by at least one arc segment. In some embodiments, the first cross section of each sub-region and the corresponding light-exiting surface can be selected from the shape group consisting of rectangle, circle, ellipse, diamond or approximate rectangle, approximately circle, approximate ellipse, and approximate diamond.

In some embodiments, the light-emitting functional layer 20 includes a light transmissive electrode 210, a light emitting layer 220, and a reflective electrode 230, and the light transmitting electrode 210 and the reflective electrode 230 are independently located on opposite sides of the light emitting layer 220. The light generated in the light emitting layer 220 can be reflected by the reflective electrode 230 and transmitted to the light extraction functional layer 30 by the light transmissive electrode 210.

In some embodiments, in order to achieve electroluminescence, the light-emitting functional layer 20 may further include a hole injection transport layer and an electron injection transport layer, a hole injection transport layer and an electron injection transport layer are located on opposite sides of the light emitting layer 220, and the light transmissive electrode 210 is located on one side of the hole injection transport layer or the electron injection transport layer away from the light emitting layer 220. In some embodiments, the light emitting layer 220 can be a quantum dot material layer or an organic light-emitting material layer. In some embodiments, the hole injection transport layer may consist of a hole injection layer and a hole transport layer which are adjacent to each other, and the electron injection transport layer may consist of an electron injection layer and an electron transport layer which are adjacent to each other.

In some embodiments, the light-emitting unit can be a quantum dot electroluminescent device (QLED), or an organic electroluminescent device (OLED), or the other kind of electroluminescent device, or an electroluminescent device combined with color conversion element.

In some embodiments, the structure of each light emitting unit is the structure A or the structure C, and the light extraction functional layer 30 can include a light extraction layer and an interface layer (not shown in the figure) which is located between the light transmissive electrode 210 and the light extraction layer. In some embodiments, a refractive index of the material of the interface layer is greater than or equal to 1.7 (preferably greater than or equal to 1.8), and a transmittance in the visible light wavelength range exceeds 80%. Those skilled in the art can select a suitable material and a preparation process of the interface layer according to the actual need, and can also change the light transmittance of the interface layer by adjusting the thickness of the interface layer.

In some embodiments, the interface layer is disposed in a light-emitting device as shown in FIG. 1, which can protect the light transmissive electrode 210. In some embodiments, the material of the interface layer can be a variety of materials which can be provided by vapor deposition, such as NPP, Alq₃, MoO₃, etc., or various sputtering materials such as silicon nitride (SiNₓ), silicon oxynitride (SiNₓ, O_{y}), etc., or a UV curable resin with the aforesaid refractive index and transmittance.

In other embodiments, the interface layer is disposed in a light-emitting device as shown in FIG. 2, which is capable of planarizing the light extraction functional layer 30 in order to make the applied light transmissive electrode 210 flat. In some embodiments, a material of the interface layer can be selected from UV curable resin with the aforesaid refractive index.

In some embodiments, the structure of each light emitting unit is the structure B, and the light extraction functional layer 30 includes a light extraction layer and an interface layer (not shown in the figure) which is located on a side of the light extraction layer away from the light transmissive substrate to protect the light extraction layer from environmental impact and improve scratch resistance, wear resistance and other properties of the light extraction functional layer. In some embodiments, a material of the interface layer may be selected from the group consisting of various IN curable resins (the curing temperature required for heat curing resins is unfavorable to the device and the device production efficiency is low), preferably a material with transmittance of more than 90% and refractive index of less than 1.5 within the visible light wavelength range, such as acrylic resin, polyurethane acrylic resin, etc., but is not limited thereto.

In some embodiments, the light-emitting device of the present disclosure is a top emitting light-emitting device, and the light transmissive substrate 10 is located on one side of the light-emitting unit. 30 away from the light extraction functional layer 30, as shown in FIG. 1.

In other embodiments, the light-emitting device of the present disclosure is a bottom emitting light-emitting device, the light-emitting unit includes the light transmissive substrate 10, and the light transmissive substrate 10 is located on one side of the light extraction functional layer 30 away from the light-emitting functional layer 20, as shown in FIG. 2.

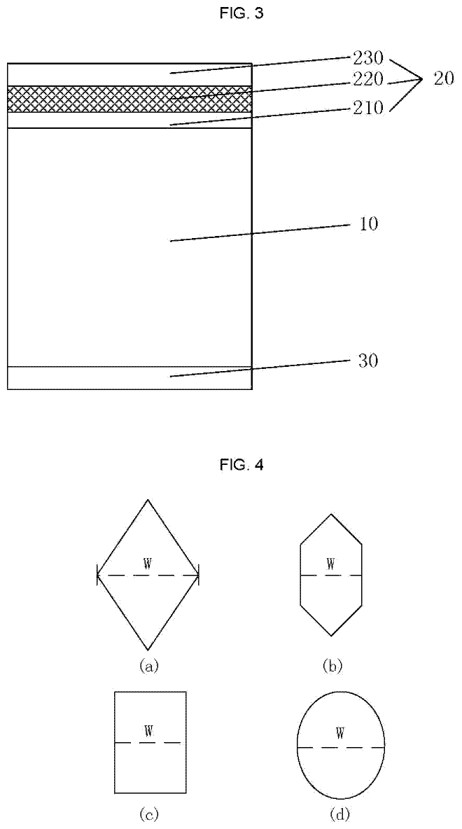

When the light-emitting device of the present disclosure is a bottom emitting light-emitting device, the structure of the light-emitting device is not limited to the above embodiment. For example, the light-emitting unit can include a light transmissive substrate 10, and the light transmissive substrate 10 is located between the light-emitting functional layer 20 and the light extraction functional layer 30, as shown in FIG. 3.

According to another aspect of the present disclosure, a display apparatus is provided, including a light-emitting device which is the aforesaid light-emitting device. In this case, the isolation structure is a pixel isolation structure (which can be called pixel definition layer or “Bank”), at least one sub-pixel region is formed between the pixel isolation structures, and the light-emitting functional layer 20 and the light extraction functional layer 30 are disposed in the sub-pixel region by one-to-one correspondence.

According to another aspect of the present disclosure, a lighting apparatus is provided, including a light-emitting device which is the aforesaid light-emitting device. In this case, the isolation structure in the light-emitting device is a frame, and the light-emitting unit is disposed within the frame.

The light-emitting device provided herein will be further described below in conjunction with the examples and comparative examples.

### Example 1

The light-emitting device provided in this example was a top emission light-emitting device, as shown in FIG. 1, including a light transmissive substrate 10, a light-emitting functional layer 20, and a light extraction functional layer 30 that were sequentially laminated, the light-emitting functional layer 20 included a light transmissive electrode 210, a hole injection transport layer (composed of the hole injection layer and the hole transport layer), a light-emitting layer 220, an electron injection transport layer and a reflective electrode 230, and the light transmissive electrode 210 and the reflective electrode 230 are independently located on opposite sides of the light-emitting layer 220, the light extraction functional layer 30 included a light extraction layer; the light-emitting device further includes a pixel isolation structure disposed on the first surface of the light transmissive substrate 10, and the pixel isolation structure formed 3*3*3 (3R, 3G, 3B) sub-pixel regions; the light-emitting functional layer 20 was disposed in the sub-pixel region by one-to-one correspondence, and the light extraction functional layer 30 was disposed in one-to-one correspondence with the light-emitting functional layer 20, a part of the light transmissive substrate 10, the light-emitting functional layer 20 and the light extraction functional layer 30 were sequentially laminated to constitute each light-emitting unit, light-exiting direction of each light-emitting unit was from the reflective electrode (230) to the light extraction functional layer 30, the thickness of T was 4 μm, the light-exiting surface of each light-emitting unit was a rectangular shape, and the shortest length W was 20 μm.

The number of the first light-emitting units that emitted red light, the second light-emitting units that emitted green light, and the third light-emitting units that emitted blue light in the above-mentioned light-emitting units were the same, the light-emitting layer in the first light emitting unit was made of red quantum dots which were mixed with solvents and then dried, wherein the red quantum dots were made of CdSe/ZnS, the light-emitting layer in the third light emitting unit was made of blue quantum dots which were mixed with solvents and then dried, wherein the blue quantum dots were made of CdZnS/ZnS, the light-emitting layer in the second light emitting unit was made of green quantum dots which were mixed with solvents and then dried, wherein the green quantum dots were made of CdSe/CdS,

The above-mentioned light transmissive electrode 210 was an ITO anode (thickness is 150 nm), the hole injection layer material was polyethylene dioxythiophene: polystyrene sulfonate, the hole transport layer material was poly(n-vinylcarbazole), the above-mentioned reflective electrode 230 was a cathode and made of silver, and the electron injection transport layer material was zinc oxide nanocrystals. The total thickness of the light-emitting unit which composed of the light-emitting layer, the hole transport layer, the hole injection layer and the electron injection transport layer was 150 nm. The interface layer was 100 nm of NPB (N,N′-bis (naphthalene-1-yl)-N, N-bis (phenyl)-benzidine) layer which was fabricated by vacuum thermal evaporation.

The light extraction layer was formed by mixing and curing 50:50 volume percentage of scattering particles and 6108 polymer LTV adhesive, and the scattering particles were P25 titanium dioxide with 21 nm average size. The thickness of the light extraction layer was 3600 nm.

### Example 2

The difference between the light-emitting device provided in this example and the Example 1 was:

The thickness of T was 1 μm, wherein the total thickness of functional layers of the light emitting unit was 150 nm, the thickness of light transmissive electrode ITO was 100 nm, the thickness of interface layer NPB was 50 nm, and the thickness of light extraction layer was 700 nm. The shortest length W of the light-exiting surface of the above light-emitting unit was 10 μm.

### Example 3

The difference between the light-emitting device provided in this example and the Example 1 was:

The thickness of T was 1 μm, wherein the total thickness of functional layers of the light emitting unit was 150 nm, the thickness of light transmissive electrode ITO was 100 nm, the thickness of interface layer NPB was 50 nm, and the thickness of light extraction layer was 700 nm. The light-exiting surface of the light-exiting unit was an elliptical shape, and the shortest length W was 20 μm.

### Example 4

The difference between the light-emitting device provided in this example and the Example 1 was:

The thickness of T was 300 nm, wherein the total thickness of functional layers of the light emitting unit was 150 nm, the thickness of light transmissive electrode Ag was 15 nm, the thickness of interface layer NPB was 20 nm, and the thickness of light extraction layer was 115 nm. The light-exiting surface of the light-exiting unit was a rhombus shape, the shortest length W was 9 μm.

### Example 5

The difference between the light-emitting device provided in this example and the Example 1 was:

As shown in FIG. 3, the light-emitting device included sequentially laminated the light-emitting functional layer 20, the light transmissive substrate 10, and the light extraction functional layer 30, the thickness of T was 0.7 mm, wherein the total thickness of functional layers of the light emitting unit was 150 nm, the thickness of light transmissive electrode ITO was 150 nm, the thickness of light transmissive substrate was 0.7 mm, and the thickness of light extraction layer was 800 nm. The thickness of T and the light transmissive substrate was approximately the same, i.e., 0.7 mm, (the light extraction layer was disposed on the outside surface of the substrate far away from the device, no interface layer needed), the shortest length W was 35 mm.

### Example 6

The difference between the light-emitting device provided in this example and the Example 1 was:

As shown in FIG. 2, the light-emitting device included the light-emitting functional layer 20, the light extraction functional layer 30 that were sequentially laminated, and the light transmissive substrate 10, the thickness of T was 50 μm, wherein the total thickness of functional layers of the light emitting unit was 150 nm, the thickness of light transmissive electrode ITO was 200 nm, the thickness of interface layer was 2.15 μm, and the thickness of light extraction layer was 2.5 μm, the thickness of light transmissive substrate was 45 μm.

The shortest length W of the light-exiting surface of the above light-emitting unit was 2 mm.

### Comparative Examples 1-6

The light-emitting devices provided in the above comparative examples were similar to Examples 1-6 respectively, but with no light extraction functional layer 30.

The thickness tests of all examples and comparative examples were tested by the DektakXT stylus profilometer, and the length test equipment was a microscope.

The external quantum efficiencies of the light-emitting devices in the above-described Examples 1-6 and Comparative Examples 1-6 were tested, and the performance test method of the QLED device was mainly divided into two parts: the first part was mainly by using the Keithley's 2400 Source Measure Unit Instrument and the probe station to measure the voltage (V) and current (I) signal of the device, further to get the current density-voltage graph and the number of electrons passing through the device within the unit time; the second part was mainly by using an integrating sphere, fibers and a spectrometer (QE65000 or QEPRO) to measure spectral data in front of the device, including the light emission peak, peak width at half height, and the number of light-emitted photons. The external quantum efficiency (EQE) of the device could be calculated by the formula according to the data that obtained in the above two parts. The devices were operated under 1000 nits of white light emission (white light with 1000 nits was made up of 300 nits of red light, 600 nits of green light and 100 nits of blue light) for aging test, the time that it took to degrade to 980 nit (T₉₈) was recorded, the test results were shown in Table 1.

TABLE 1

| / | Example 1 | Example 2 | Example 3 | Example 4 | Example 5 | Example 6 |
|---|---|---|---|---|---|---|
| EQE % | 11.3 | 12.7 | 18.1 | 20.4 | 14.5 | 21.3 |
| T₉₈/h | 2665 | 2930 | 5396 | 6836 | 3829 | 7980 |
| | Comparative | Comparative | Comparative | Comparative | Comparative | Comparative |
| / | Example 1 | Example 2 | Example 3 | Example 4 | Example 5 | Example 6 |
| EQE % | 9.1 | 8.9 | 9.3 | 9.6 | 9.4 | 9.9 |
| T₉₈/h | 1691 | 1536 | 1721 | 1901 | 1705 | 2104 |

As can be seen from the above test results, compared with the light-emitting devices that without light extraction functional layer which provided in the comparative examples, the external quantum efficiencies of the light-emitting devices that with light extraction functional layer which provided in the above examples were all improved, no matter whether the active area of the light-emitting device was small or large, the improvement ratio of light extraction efficiency increased significantly when the T/W ratio was decreased, it can be seen from the T₉₈ which means degrading to 98% of its initial brightness, the lifetime of the device that with light extraction functional layer was significantly improved. In the first and second group of devices, the T/W ratio was only around 1/5 and 1/10 respectively, and the improvement ratio of light extraction efficiency was approximately 24% and 45% respectively. The devices in the fifth group were relatively special, the light extraction functional layer can only extract light in the substrate wave guided mode (that was the so-called external light extraction, the rest was internal light extraction), so even if the T/W ratio was small the improvement ratio of light extraction efficiency was only 50%, compared to the devices in the first and second group, (the first group devices refer to the devices consisting of device of Example 1 and device of Comparative Example 1, and so on), the improvement ratio was still significantly improved.

Under some circumstances, the light-emitting active area of the light-emitting device is strictly limited, that is to say, the pixel is getting smaller and smaller, in order to improve its external quantum efficiency, it is necessary to carefully design the light path of the device, and make the ratio of T/W as small as possible to obtain a higher improvement ratio.

In addition, the devices in Examples 1-6 were checked by naked-eye inspection and microscope inspection, except for the device in Example 5 had a blur light-emitting edge, there was no blur or light color mixing phenomenon in other remaining examples. The device structure of FIG. 2 was more suitable for the lighting device, and the device structures of FIG. 1 and FIG. 3 can be used for display device with proper design and optical path control.

### Comparative Example 7

The difference between the light-emitting device provided in this example and the Example 5 was: the shortest length W of the light-exiting surface of the above light-emitting unit was 0.7 mm.

### Comparative Example 8

The difference between the light-emitting device provided in this example and the Example 5 was: the shortest length W of the light-exiting surface of the above light-emitting unit was 0.5 mm.

### Comparative Example 9

The difference between the light-emitting device provided in this example and the Comparative Example 7 was: the light extraction functional layer 30 was not provided in the light-emitting device.

### Comparative Example 10

The difference between the light-emitting device provided in this example and the Comparative Example 8 was: the light extraction functional layer 30 was not provided in the light-emitting device.

It should be noted that the Comparative Examples 7-10 were control experiments designed by inventors, did not belong to prior art. The external quantum efficiency and T₉₈ of light-emitting devices in the above Comparative Examples 7-10 were tested, and the test results were shown in Table 2.

TABLE 2

| | Comparative | Comparative | Comparative | Comparative |
|---|---|---|---|---|
| / | Example 7 | Example 8 | Example 9 | Example 10 |
| EQE % | 7.4 | 5.5 | 8.3 | 7.9 |
| T₉₈/h | 1294 | 980 | 1423 | 1399 |

As can be seen from the test results of Table 1 and Table 2, when T=W or T>W, whether the light extraction functional layer was set or not, the external quantum efficiency of such device was lower than the device with T<W, and the brightness degraded rate was also faster; in addition, when T=W or T>W, the introduction of the light extraction functional layer reduced the efficiency of the device, and the latter's (T>W) reduction extent was greater, so that the brightness of the device was degraded faster.

From the above description, it can be seen that the embodiments of the present disclosure achieve the following technical effects:

W is defined as the shortest length of a straight line segment which passes through geometric center of a light-exiting surface of each light-emitting unit and whose two ends respectively connects with edge of the light-exiting surface, by making the thickness T less than W, enabling the light extraction functional layer to meet the universally applicable application conditions, therefore, whether it is applied to small area light-emitting devices or large area light-emitting devices, it is possible to have a significant light extraction effect, thereby increasing the light output efficiency of light-emitting unit, and extending the lifetime of the device.

The foregoing embodiments are only preferred embodiments of the present disclosure, and cannot be used to limit the scope of protection of the present disclosure. Any insubstantial changes and substitutions made by those skilled in the art on the basis of the present disclosure belong to the protection scope of the present disclosure.

1. A light-emitting device, comprising:
a light transmissive substrate;
an isolation structure, disposed on a first surface of the light transmissive substrate, forming at least one sub-region by the isolation structure;
a light-emitting functional layer, disposed in the sub-region by one-to-one correspondence, comprising a light transmissive electrode (210), a light emitting layer and a reflective electrode, wherein the light transmissive electrode and the reflective electrode are independently located on opposite sides of the light emitting layer;
a light extraction functional layer, disposed in one-to-one correspondence with the light-emitting functional layer;
wherein, the light-emitting functional layer, the light extraction functional layer and a part of the light transmissive substrate, which are stacked by one-to-one correspondence, constitute each light-emitting unit; structure of each light-emitting unit is selected from structure A, structure B and structure C, the structure A comprises the light-emitting functional layer, the light extraction functional layer and the part of the light transmissive substrate which are successively stacked, the structure B comprises the light-emitting functional layer, the part of the light transmissive substrate and the light extraction functional layer which are successively stacked, and the structure C comprises the light extraction functional layer, the light-emitting functional layer and the part of the light transmissive substrate which are successively stacked; light-exiting direction of the structure A and the structure B is from the reflective electrode to the light transmissive substrate and light-exiting direction of the structure C is from the reflective electrode to the light extraction functional layer;
a straight line segment that passes through geometric center of a light-exiting surface of each light-emitting unit and whose two ends are respectively connected with edge line of the light-exiting surface is defined as a first straight line segment, and the shortest length of the first straight line segment is defined as W; in a direction perpendicular to the light transmissive substrate, a thickness difference of the light-emitting unit and the reflective electrode is defined as T in the structure A and the structure B, and a thickness difference of sum of thickness of the light extraction functional layer and the light-emitting functional layer and the thickness of the reflective electrode is defined as T in the structure C; in the structure A, the structure B and the structure C, the T is less than the W.

2. The light-emitting device according to claim 1, wherein, T/W [symbol] 1/10.

3. The light-emitting device according to claim 2, wherein, T/W [symbol] 1/20.

4. The light-emitting device according to claim 2, wherein, T/W [symbol] 1/30.

5. The light-emitting device according to claim 1, wherein, 300 nm [symbol] T [symbol] 1 mm, W [symbol] 3 μm.

6. The light-emitting device according to claim 1, wherein, the light-exiting surface has a pattern of polygon formed by a plurality of straight line segments or a pattern surrounded by at least one arc segment.

7. The light-emitting device according to claim 1, wherein, the light-emitting functional layer further comprises a hole injection transport layer and an electron injection transport layer, the hole injection transport layer and the electron injection transport layer are located on opposite sides of the light emitting layer, and the light transmissive electrode is located on a side of the hole injection transport layer or the electron injection transport layer away from the light emitting layer.

8. The light-emitting device according to claim 7, wherein the light emitting layer is a quantum dot light emitting layer or an organic luminescent material layer.

9. The light-emitting device according to claim 1, wherein, the structure of each light emitting unit is the structure A or the structure C, and the light extraction functional layer comprises a light extraction layer and an interface layer which is located between the light transmissive electrode and the light extraction layer.

10. The light-emitting device according to claim 1, the light-emitting device comprising a plurality of the light-emitting units for emitting different colors of light, and the different colors of light being independently selected from at least one of red light, green light, blue light and white light.

11. The light-emitting device according to claim 1, the light-emitting device being one of an OLED device, a LED device and a QLED device.

12. The light-emitting device according to claim 1, wherein, the structure of each light emitting unit is the structure B, and the light extraction functional layer comprises a light extraction layer and an interface layer which is located on a side of the light extraction layer away from the light transmissive substrate.

13. A display apparatus, comprising a light-emitting device which is the light-emitting device according to claim 1, wherein the isolation structure is a pixel isolation structure, and the sub-region is a sub-pixel region.

14. A lighting apparatus, comprising a light-emitting device which is the light-emitting device according to claim 1, wherein the isolation structure is a frame, and the light-emitting unit is disposed within the frame.

15. The light-emitting device according to claim 2, wherein, the structure of each light emitting unit is the structure A or the structure C, and the light extraction functional layer comprises a light extraction layer and an interface layer which is located between the light transmissive electrode and the light extraction layer.

16. The light-emitting device according to claim 2, wherein, the structure of each light emitting unit is the structure B, and the light extraction functional layer comprises a light extraction layer and an interface layer which is located on a side of the light extraction layer away from the light transmissive substrate.

17. The display apparatus according to claim 13, wherein, T/W [symbol] 1/10.

18. The display apparatus according to claim 13, wherein, T/W [symbol] 1/20.

19. The display apparatus according to claim 13, wherein, T/W [symbol] 1/30.

20. The display apparatus according to claim 13, wherein, 300 nm [symbol] T [symbol] 1 mm, W [symbol] 3 μm.
